(19) United States
(12) Patent Application Publication
(10) Pub. No.: US 2002/0135354 A1
(43) Pub. Date: Sep. 26, 2002

(54) Current sensor, current measuring method, and switch circuit

(76) Inventor: Fumihiko Hirose, Yokohama-shi (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(21) Appl. No.: 10/139,399

(22) Filed: May 7, 2002

Related U.S. Application Data
(63) Continuation of application No. PCT/JP01/07746, filed on Sep. 6, 2001.

(30) Foreign Application Priority Data
Sep. 8, 2000 (JP) 2000-273363

(51) Int. Cl. G01R 1/00; H01F 5/00

(52) U.S. Cl. 324/127; 336/200

(57) ABSTRACT

A current sensor according to the present invention comprises a multilayer substrate comprising two or more layers, a through-hole provided to pierce the multilayer substrate from the front face to the rear face, a coil formed by connecting a wiring on the front face with a wiring on the rear face via the through-hole, and a wire pattern arranged so as to thread through the coil. When a current is applied to the wire pattern, the current sensor detects a voltage generated at both ends of the coil.

### CROSS-REFERENCE TO RELATED APPLICATIONS

This is a Continuation Application of PCT Application No. PCT/JP01/07746, filed Sep. 6, 2001, which was not published under PCT Article 21(2) in English.

This application is based upon and claims the benefit of priority from the prior Japanese Patent Application No. 2000-273363, filed Sep. 8, 2000, the entire contents of which are incorporated herein by reference.

### BACKGROUND OF THE INVENTION

1. Field of the Invention

The present invention relates to a current sensor, a current measuring method, and a switch circuit.

2. Description of the Related Art

Conventionally, an electronic switch, a chopper, or an inverter transmits power from a power supply to a load by repeatedly turning an electronic switch on and off.

FIG. 9 shows an example of a switch circuit using a chopper. The circuit connects a power supply 11 with a load 12 via an electronic switch 13 and a current sensor 14. The electronic switch 13 uses a control circuit 15 for an on/off operation. In addition, a current sensor 14 is used to detect the current transmitted to the load 12 from the power supply 11. When an overcurrent occurs, the electronic switch 13 turns off momentarily to protect the electronic switch 13 itself, the load 12, and the power supply 11 against failure. Normally, a bipolar transistor, a field effect transistor, or an IGBT (Insulated Gate Bipolar Transistor) is used for the electronic switch 13.

A resistor or a current transformer (abbreviated as CT hereinafter) may be available for the current sensor 14. Since the resistor causes a loss of power, however, the CT is used for decreasing the loss.

Compared with the resistor, however, the CT uses large parts. Structurally, wires must be threaded into the coil. Packaging of the assembly becomes complicated.

### BRIEF SUMMARY OF THE INVENTION

The object of the present invention is to provide a current sensor, a current measuring method, and a switch circuit for facilitating automatic packaging of the current transformer.

A current sensor according to the present invention comprises: a multilayer substrate comprising two or more layers; a through-hole provided to pierce the multilayer substrate from the front face to the rear face; a coil formed by connecting a wiring on the front face with a wiring on the rear face via the through-hole; and a wire pattern arranged to thread through the coil, wherein when a current is applied to the wire pattern, the current sensor detects a voltage generated at both ends of the coil.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 schematically shows a configuration of a current sensor according to a first embodiment of the present invention;

FIG. 2 is a detail view of the current sensor according to the first embodiment of the present invention, showing patterns on the top, inside, and bottom surfaces overlapped with each other;

FIG. 3 is a detail view of the current sensor according to the first embodiment of the present invention, showing the pattern on the top surface;

FIG. 4 is a detail view of the current sensor according to the first embodiment of the present invention, showing the pattern on the inside surface;

FIG. 5 is a detail view of the current sensor according to the first embodiment of the present invention, showing the pattern on the bottom surface;

FIGS. 6A and 6B show examples of the current sensor according to the first embodiment of the present invention inserted into a wire to be measured;

FIG. 7 shows an example of a switch circuit by integrating the current sensor according to the first embodiment of the present invention with an electronic switch;

FIG. 8 is a detail view of a current sensor according to a second embodiment of the present invention, showing patterns on the top, inside, and bottom surfaces overlapped with each other; and

FIG. 9 is a schematic diagram of a switch circuit according to the prior art.

### DETAILED DESCRIPTION OF THE INVENTION

Embodiments of the present invention will be described in further detail with reference to the accompanying drawings.

FIG. 1 schematically shows a configuration of a current sensor according to a first embodiment of the present invention. The current sensor contains a built-in CT as current detection by using a multilayer substrate as a packaging substrate. The multilayer substrate has a multilayer structure comprising at least two layers, i.e., insulating plates laminated. The first embodiment shows an example of a two-layer substrate. A conductive wiring pattern is provided on each of the top surface (front face), bottom surface (rear face), and inside surfaces of the laminated plates.

The current sensor contains terminal pads A and B on a top surface 1 which are used as leading wirings to detect a current. The terminal pads A and B connect with a wiring pattern on an inside surface 2 via through-holes. Two terminal pads CT1 and CT2 for CT output are provided on the top surface 1. The row structures of wirings are formed on the top and bottom surfaces 1 and 3 and are connected in a coil by means of through-holes. Both ends of a coil 4 are each connected to the terminal pads A and B on the top surface 1 by means of pattern wirings. A rectilinear or curvilinear pattern wire connects between the terminal pads A and B on the inside surface 2 and is arranged so as to pass inside the coil 4. The structure will be described hereinafter in detail with reference to detail views.

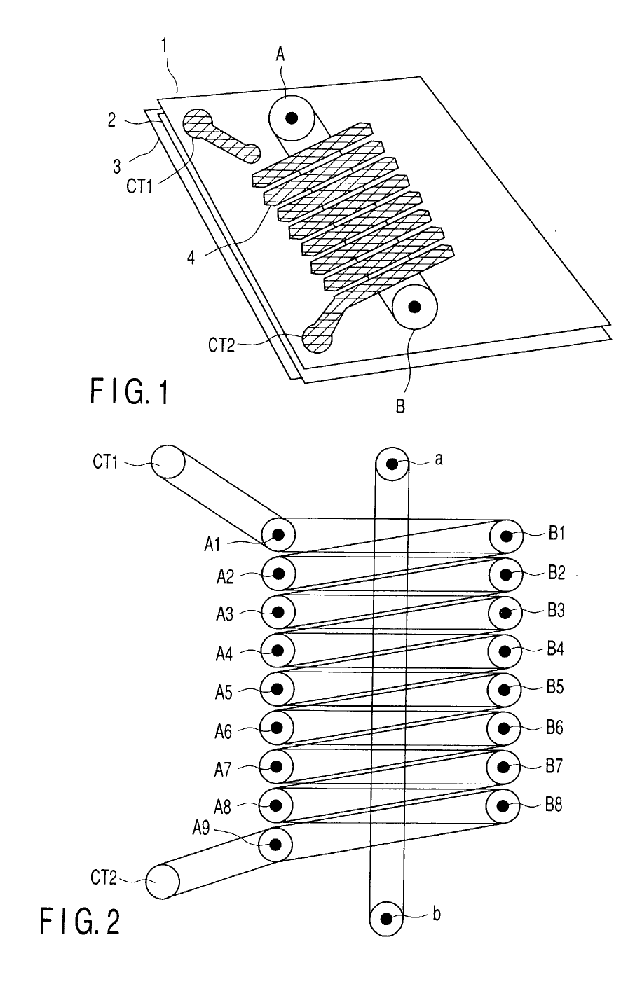

FIG. 2 is a detail view of the current sensor having the above-mentioned structure, showing patterns on the top surface 1, the inside surface 2, and the bottom surface 3 overlapped with each other. The reference symbols Al through A9, B1 through B8, and a and b denote through-holes for connecting the surfaces with each other.

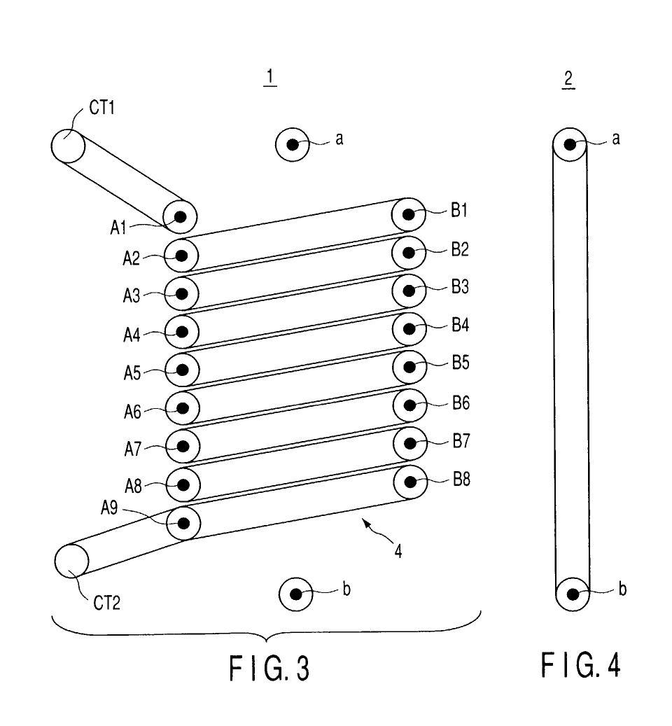

FIG. 3 shows a pattern on the top surface 1. FIG. 4 shows a pattern on the inside surface 2. FIG. 5 shows a pattern on the bottom surface 3. According to the structure, the row structures of wirings are formed on the top and bottom surfaces 1 and 3 and are connected via through-holes A1 through A9, and B1 through B8 to form the coil 4. Both ends of the coil 4 are connected to the terminal pads CT1 and CT2. The wiring for current detection is connected to the pattern wire on the inside surface 2 via the through-holes a and b.

The structure does not limit the number of turns for the coil. A large number of turns increases the sensitivity for detecting a current but enlarges the wiring area. For actual use, the number of turns needs to be increased to be as many as possible within an allowable area. Namely, in order to form a coil, one or more rectilinear or curvilinear conductive patterns are arranged on the top and bottom surfaces of the substrate. Through-holes are used to connect the conductive patterns on the top and bottom surfaces in a spiral or coiled shape.

When a current flows between the terminal pads A and B of the current sensor configured as mentioned above, an induced electromotive force occurs between both ends of the coil 4 (between CT1 and CT2). The voltage induced at both ends of the coil 4 is proportional to the current flowing between the terminal pads A and B. Accordingly, it is possible to measure a current between terminal pads A and B by detecting a voltage occurring at both ends of the coil.

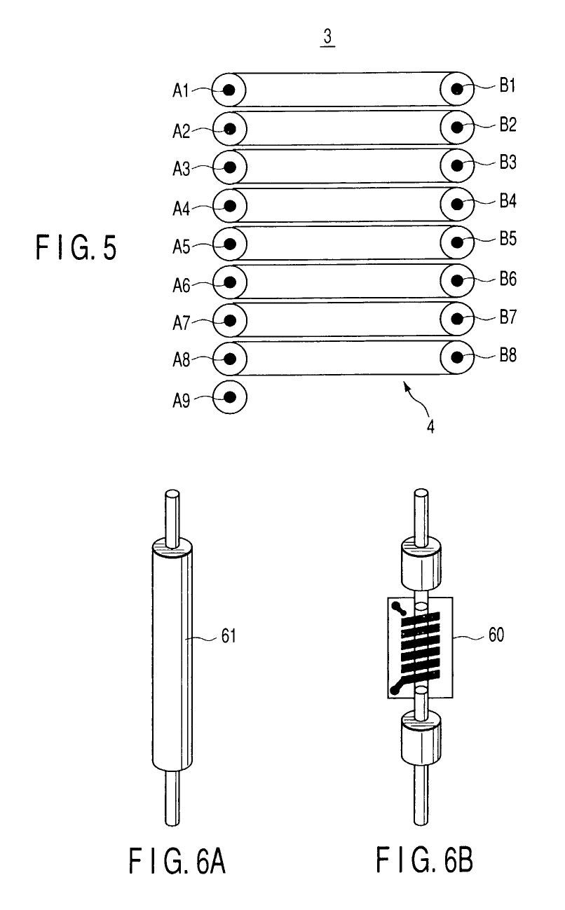

FIGS. 6A and 6B show examples of the current sensor having the above-mentioned configuration inserted into a wire, the current through which is to be measured. When there is a wire, the current through which is to be measured, as shown in FIG. 6A, a current sensor 60 according to the present invention is inserted into a path 61 of the wire as shown in FIG. 6B. The wire is connected to the substrate's wiring pattern of the current sensor 60 to pass a current. A current detection signal is obtained from the current sensor 60 to enable measurement of the current flowing through the wire path 61.

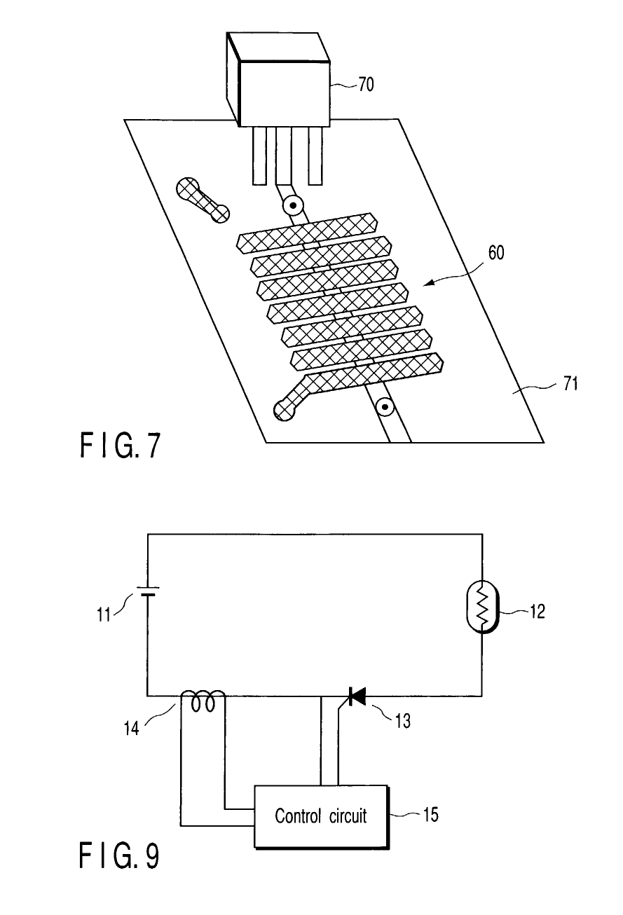

FIG. 7 shows an example of a switch circuit by integrating the current sensor having the above-mentioned configuration with an electronic switch. As shown in FIG. 7, the current sensor 60 is integrated with an electronic switch 70 on the same substrate 71 to allow the current sensor 60 to detect a current for the electronic switch 70. This makes it possible to monitor a current flowing through the electronic switch 70 and turn the switch off in the event of an overcurrent. Consequently, it is possible to prevent failure of the electronic switch due to overcurrent and improve the reliability of the switch circuit.

The electronic switch 70 comprises a transistor, a MOS-FET (Metal Oxide Semiconductor Field Effect Transistor), an IGBT (Insulated Gate Bipolar Transistor), etc. It is also possible to configure a switch circuit by unifying the current sensor and the electronic switch with resin, etc., instead of integrating them on the same substrate.

The CT for current detection is already built in the current sensor according to the first embodiment during manufacture of the printed circuit board. It is thus possible to solve the conventional problems of costs for CT packaging or difficulties about automatic packaging. The cost for the CT itself can be also reduced.

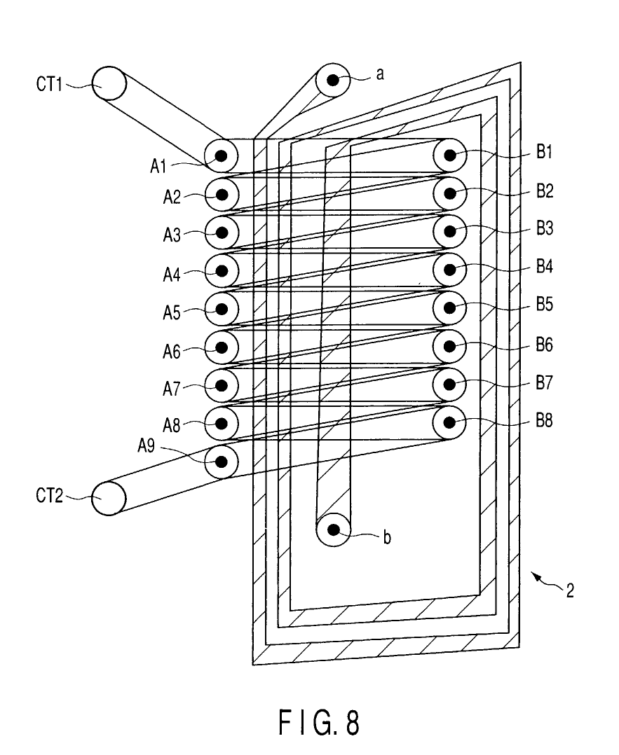

FIG. 8 is a detail view of a current sensor according to a second embodiment of the present invention, showing patterns on the top, inside, and bottom surfaces overlapped with each other of a current sensor having the above-mentioned configuration. In order to increase the sensitivity for detecting a current, it may be preferable to provide a configuration so as to coil a pattern wire on the inside surface 2 and allow it to thread through the coils formed on the top and bottom surfaces.

As a specific example, we fabricated a current sensor using the present invention and investigated whether or not a current can be detected.

A printed circuit board was formed by laminating two substrates each 0.5 mm thick. Patterns as shown in FIGS. 3, 4, and 5 were formed on the top surface 1, the inside surface (joint surface) 2, and the bottom surface 3, respectively. The patterns on the respective surfaces were connected at through-hole A1 through A9, and B1 through B8 to form the coil 4. A square-wave current was applied to the wiring between through-holes a and b threading through the coil 4. The current indicated a maximum of 20 A and a minimum of 0 A. The square wave frequency was 50 kHz.

When the current was passed through in the example, we confirmed that a pulse signal of several hundred microvolts was generated between the terminal pads CT1 and CT2. We found that the pulse height of the pulse signal is completely proportional to the current passing between the terminal pads A and B, and that it is possible to measure the strength of a current passing therebetween by knowing that pulse height.

The present invention is not limited to the above-mentioned embodiments and examples. It is further understood that various changes and modifications may be made in the present invention without departing from the spirit and scope thereof.

The current sensor according to the present invention facilitates automatic packaging of a current transformer because the current transformer for current detection is built in during manufacture of the substrate.

The current sensor according to the present invention makes it possible to easily arrange wire patterns in a multilayer substrate.

The current sensor according to the present invention makes it possible to easily provide a coil on a multilayer substrate.

The current sensor according to the present invention makes it possible to easily provide a coil on a multilayer substrate.

The current measuring method according to the present invention makes it possible to easily measure a current in a current path by arranging the current sensor in the current path.

The switch circuit according to the present invention can monitor a current passing through an electronic switch and turn off the electronic switch in the event of an overcurrent. Consequently, it is possible to prevent failure of the electronic switch due to overcurrent and improve the reliability of the switch circuit.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A current sensor comprising:
a multilayer substrate comprising two or more layers;
a through-hole provided to pierce said multilayer substrate from the front face to the rear face;
a coil formed by connecting a wiring on said front face with a wiring on said rear face via said through-hole; and
a wire pattern arranged to thread through said coil, wherein
when a current is applied to said wire pattern, said current sensor detects a voltage generated at both ends of said coil.

2. The current sensor according to claim 1, wherein said wire pattern is arranged on a joint surface of said substrate.

3. The current sensor according to claim 1, wherein said coil is formed by arranging one or more conductive patterns on each of said front and rear faces and connecting said conductive patterns on said front and rear faces via said through-hole.

4. The current sensor according to claim 2, wherein said coil is formed by arranging one or more conductive patterns on each of said front and rear faces and connecting said conductive patterns on said front and rear faces via said through-hole.

5. A current measuring method using the current sensor described in claim 1 comprising:
arranging said multilayer substrate near a current path to be measured;
connecting said path to a wiring pattern on said substrate to apply a current; and
measuring a current passing through said path.

6. A current measuring method using the current sensor described in claim 2 comprising:
arranging said multilayer substrate near a current path to be measured;
connecting said path to a wiring pattern on said substrate to apply a current; and
measuring a current passing through said path.

7. A current measuring method using the current sensor described in claim 3 comprising:
arranging said multilayer substrate near a current path to be measured;
connecting said path to a wiring pattern on said substrate to apply a current; and
measuring a current passing through said path.

8. A current measuring method using the current sensor described in claim 4 comprising:
arranging said multilayer substrate near a current path to be measured;
connecting said path to a wiring pattern on said substrate to apply a current; and
measuring a current passing through said path.

9. A switch circuit having a configuration of integrating an electronic switch and the current sensor described in claim 1.

10. A switch circuit having a configuration of integrating an electronic switch and the current sensor described in claim 2.

11. A switch circuit having a configuration of integrating an electronic switch and the current sensor described in claim 3.

12. A switch circuit having a configuration of integrating an electronic switch and the current sensor described in claim 4.
